(19) United States
(12) Patent Application Publication
(10) Pub. No.: US 2025/0140950 A1
(43) Pub. Date: May 1, 2025

(54) AUTOMOTIVE LITHIUM-ION BATTERY AND PROTECTION CIRCUIT THEREOF

(71) Applicant: Samsung SDI Co., Ltd., Yongin-si (KR)

(72) Inventor: Hyeoncheol Jeong, Yongin-si (KR)

(73) Assignee: Samsung SDI Co., Ltd., Yongin-si (KR)

(21) Appl. No.: 18/933,029

(22) Filed: Oct. 31, 2024

(30) Foreign Application Priority Data
Nov. 1, 2023 (KR) 10-2023-0149268

(51) Int. Cl. H01M 10/42; B60R 16/033; H01M 10/0525; H01M 50/51; H01M 50/574

(52) U.S. Cl. CPC H01M 10/4264; B60R 16/033; H01M 10/0525; H01M 50/51; H01M 50/574; H01M 2220/20

(57) ABSTRACT

Provided is an automotive lithium-ion battery. The automotive lithium-ion battery includes a battery including a plurality of lithium-ion battery cells connected in series between first and second battery terminals, a metal-oxide-semiconductor field-effect transistor (MOSFET) switch connected between the battery and a pack terminal, a start detection circuit configured to receive a start signal and output a start detection signal for a set period of time in response to the start signal, a voltage comparison circuit configured to output a voltage comparison signal by comparing a battery voltage of the battery with a reference voltage, and a switch control circuit configured to output a switch control signal for controlling the MOSFET switch based on the start detection signal and the voltage comparison signal.

### CROSS-REFERENCE TO RELATED APPLICATIONS

This present application claims priority to and the benefit of Korean Patent Application No. 10-2023-0149268, filed on Nov. 1, 2023, in the Korean Intellectual Property Office, the entire disclosure of which is incorporated herein by reference.

### FIELD

One or more embodiments relate to an automotive lithium-ion battery, and more particularly, to an automotive lithium-ion battery that may replace a lead-acid battery used in a conventional combustion engine vehicle and a protection circuit of the automotive lithium-ion battery.

### BACKGROUND

Lead-acid batteries are used to supply cranking current to motors and supply power to electrical loads such as headlights when starting conventional internal combustion engine vehicles or motorcycles. Secondary batteries are replacing automotive lead-acid batteries due to their advantageous characteristics such as relatively high energy density, relatively long life, and relatively wide operating temperature range. For example, lithium iron phosphate battery with similar operating voltages may be used instead of lead-acid batteries.

In order to use other types of lithium-ion batteries with higher operating voltages than lead-acid batteries, electrical systems of vehicles such as automotive alternators should be changed together.

### SUMMARY

One or more embodiments include an automotive lithium-ion battery that may be used instead of a lead-acid battery without changing an electrical system of a vehicle.

One or more embodiments include a protection circuit that enables an automotive lithium-ion battery to be used instead of a lead-acid battery without changing an electrical system of a vehicle.

However, the technical problems to be solved by the present disclosure are not limited thereto, and other unmentioned technical problems will be understood by one of ordinary skill in the art from the following description of the present disclosure.

Additional aspects will be set forth in part in the description which follows and, in part, will be apparent from the description, or may be learned by practice of the presented embodiments.

According to one or more embodiments of the present disclosure, an automotive lithium-ion battery includes a battery including a plurality of lithium-ion battery cells connected in series between a first battery terminal and a second battery terminal, a metal-oxide-semiconductor field-effect transistor (MOSFET) switch connected between the battery and a pack terminal, a start detection circuit configured to receive a start signal and output a start detection signal for a set period of time in response to the start signal, a voltage comparison circuit configured to output a voltage comparison signal by comparing a battery voltage of the battery with a reference voltage, and a switch control circuit configured to output a switch control signal for controlling the MOSFET switch based on the start detection signal and the voltage comparison signal.

According to some embodiments, the plurality of lithium-ion battery cells may have a three-series connection configuration.

According to some embodiments, the plurality of lithium-ion battery cells may be LCO, NCM, NCA, or LMO battery cells having a full charge voltage of 4 V or more.

According to some embodiments, the MOSFET switch may be a p-type MOSFET switch connected between the first battery terminal and a first pack terminal.

According to some embodiments, the start detection circuit may include a start switch and a start capacitor connected in series between the first battery terminal and an intermediate node, and a start resistor connected between the intermediate node and the second battery terminal. The intermediate node may be configured to output the start detection signal having a high level only for the set period of time when the start switch is turned on in response to the start signal.

According to some embodiments, the start detection circuit may further include a discharge circuit connected in parallel to the start capacitor. The discharge circuit may be configured to discharge charges stored in the start capacitor when the start switch is turned off.

According to some embodiments, the voltage comparison circuit may include a comparator including a negative input terminal to which a first voltage corresponding to the battery voltage is input and a positive input terminal to which a second voltage corresponding to the reference voltage is input, The comparator may be configured to output the voltage comparison signal having a high level when the battery voltage is lower than the reference voltage.

According to some embodiments, the switch control circuit may be a NOR gate configured to perform a NOR logic operation on the start detection signal and the voltage comparison signal and output the switch control signal to the MOSFET switch.

According to some embodiments, the switch control circuit may include an OR gate configured to perform an OR logic operation on the start detection signal and the voltage comparison signal and output a logic signal, and an n-type MOSFET switch connected between the second battery terminal or a second pack terminal and a gate of the MOSFET switch to output the switch control signal having a low level in response to the logic signal having a high level.

According to some embodiments, the start detection circuit may include a start resistor connected between the first battery terminal and an intermediate node, and a start capacitor and a start switch connected in series between the intermediate node and the second battery terminal. The intermediate node may be configured to output the start detection signal having a low level only for the set period of time when the start switch is turned on in response to the start signal.

According to some embodiments, the voltage comparison circuit may include a comparator including a positive input terminal to which a first voltage corresponding to the battery voltage is input and a negative input terminal to which a second voltage corresponding to the reference voltage is input. The comparator may be configured to output the voltage comparison signal having a low level when the battery voltage is lower than the reference voltage.

According to some embodiments, the switch control circuit may be an AND gate configured to perform an AND logic operation on the start detection signal and the voltage comparison signal and output the switch control signal to the MOSFET switch.

According to some embodiments, the MOSFET switch may be an n-type MOSFET switch connected between the second battery terminal and a second pack terminal.

According to some embodiments, the start detection circuit may include a start switch and a start capacitor connected in series between the first battery terminal and an intermediate node, and a start resistor connected between the intermediate node and the second battery terminal. The intermediate node may be configured to output the start detection signal having a high level only for the set period of time when the start switch is turned on in response to the start signal.

According to some embodiments, the voltage comparison circuit may include a comparator including a positive input terminal to which a first voltage corresponding to the battery voltage is input and a negative input terminal to which a second voltage corresponding to the reference voltage is input. The comparator may be configured to output the voltage comparison signal having a high level when the battery voltage is lower than the reference voltage.

According to some embodiments, the switch control circuit may be an OR gate configured to perform an OR logic operation on the start detection signal and the voltage comparison signal and output the switch control signal to the MOSFET switch.

According to one or more embodiments of the present disclosure, a protection circuit includes a metal-oxide-semiconductor field-effect transistor (MOSFET) switch connected between a pack terminal and a first battery terminal to which a plurality of lithium-ion battery cells are connected in series, a start detection circuit configured to receive a start signal and output a start detection signal for a set period of time in response to the start signal, a voltage comparison circuit configured to output a voltage comparison signal by comparing a battery voltage between the first battery terminal and a second battery terminal with a reference voltage, and a switch control circuit configured to output a switch control signal for controlling the MOSFET switch based on the start detection signal and the voltage comparison signal.

According to some embodiments, the start detection circuit may include a resistor-capacitor (RC) differential circuit including a start switch and a start capacitor connected in series between the first battery terminal and an intermediate node configured to output the start detection signal, and a start resistor connected between the intermediate node and the second battery terminal.

According to some embodiments, the voltage comparison circuit may include a comparator configured to receive a first voltage corresponding to the battery voltage and a second voltage corresponding to the reference voltage and output the voltage comparison signal by comparing the first voltage with the second voltage.

According to some embodiments, the switch control circuit may include a logic gate circuit configured to perform a logic operation on the start detection signal and the voltage comparison signal and output the switch control signal.

### BRIEF DESCRIPTION OF THE DRAWINGS

The accompanying drawings illustrate preferred embodiments and together with the foregoing disclosure, serve to provide further understanding of the technical features of the present disclosure, and thus, the present disclosure is not construed as being limited to the drawings, in which:

FIG. 1 is a diagram schematically illustrating an electrical system of a vehicle, according to some embodiments of the present disclosure;

FIG. 2 is a block diagram illustrating an automotive lithium-ion battery, according to some embodiments of the present disclosure;

FIG. 3 is a block diagram illustrating an automotive lithium-ion battery, according to some embodiments of the present disclosure;

FIG. 4 is a block diagram illustrating an automotive lithium-ion battery, according to some embodiments of the present disclosure;

FIG. 5 is a block diagram illustrating an automotive lithium-ion battery, according to some embodiments of the present disclosure;

FIG. 6 is a block diagram illustrating an automotive lithium-ion battery, according to some embodiments of the present disclosure;

FIGS. 7A and 7B are a perspective view and a cross-sectional view illustrating a cylindrical lithium-ion battery cell mounted on an automotive lithium-ion battery, according to some embodiments of the present disclosure;

FIG. 8 is a partial perspective view illustrating a structure of a pouch-type lithium-ion battery cell mounted on an automotive lithium-ion battery, according to some embodiments of the present disclosure;

FIG. 9A is a perspective view illustrating a prismatic lithium-ion battery cell mounted on an automotive lithium-ion battery, according to some embodiments of the present disclosure; and FIG. 9B is a cross-sectional view taken along line II-II of FIG. 9A.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” if preceding a list of elements, modify the entire list of elements and do not modify the individual elements of the list.

Hereinafter, exemplary embodiments of the present disclosure will be described in detail with reference to the accompanying drawings. Prior to the description, it should be understood that the terms used in the specification and the appended claims should not be construed as limited to general and dictionary meanings, but interpreted based on the meanings and concepts corresponding to technical aspects of the present disclosure on the basis of the principle that the inventor is allowed to define terms appropriately for the best explanation. Therefore, the description proposed herein is just a preferable example for the purpose of illustrations only, not intended to limit the scope of the present disclosure, so it should be understood that other equivalents and modifications could be made thereto without departing from the scope of the present disclosure.

It will be understood that the terms “comprise or include” and/or “comprising or including,” if used in this specification, specify the presence of stated shapes, numbers, steps, operations, members, elements, and/or groups thereof, but do not preclude the presence or addition of one or more other shapes, numbers, steps, operations, members, elements, and/or groups thereof. The use of “may” if describing embodiments of the present disclosure may refer to “one or more embodiments.”

In order to help the understanding of the present disclosure, the accompanying drawings are not drawn to scale, but dimensions of some components may be exaggerated. Also, the same reference numerals may be assigned to the same components in different embodiments.

If it is explained that two objects are identical, this means that these objects are ‘substantially identical’. The substantially identical objects may include a deviation considered low in the art, for example, a deviation of less than 5%. If it is explained that certain parameters are uniform in a certain region, this may mean that the parameters are uniform in terms of an average.

It will be understood that, although the terms “first,” “second,” etc. may be used herein to describe various elements, these elements should not be limited by these terms. These terms are only used to distinguish one element from another element. Thus, for example, a first element could be termed a second element without departing from the scope of the present disclosure.

As used herein, the singular forms are intended to include the plural forms as well, unless the context clearly indicates otherwise.

Hereinafter, it will be understood that an element is referred to as being “above (or below)” or “on (or under)” another, it may be on an upper surface (or a lower surface) of the other element and intervening elements may be present between the element and the other element on (or under) the element.

If components are described as “connected,” “coupled,” or “linked” to another component, it may mean that the components are directly “connected,” “coupled,” or “linked” or are indirectly “connected,” “coupled,” or “linked” via a third component. Also, if a certain portion is electrically coupled to another portion, the certain portion may directly connected to the other portion, or connected to the other portion with an intervening element therebetween.

If “A and/or B” throughout the specification, it means A, B, or both A and B unless otherwise described. In this regard, “and/or” includes any or all combinations of one or more of the associated listed items. to the expression “C to D” means C or higher and D or lower unless otherwise described.

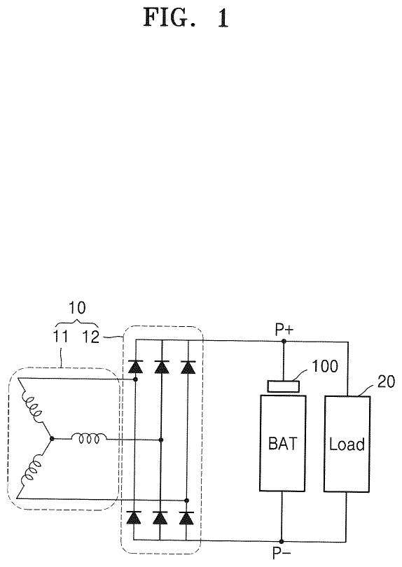

FIG. 1 is a diagram schematically illustrating an electrical system of a vehicle, according to some embodiments of the present disclosure.

Referring to FIG. 1, an electrical system of a vehicle includes an alternator 10 configured to generate direct current (DC) power, an automotive lithium-ion battery 100 in which the generated DC power is stored, and an electrical load 20 driven by using the DC power stored in the automotive lithium-ion battery 100.

The alternator 10 includes a stator 11 and a regulator 12. As a rotor magnetized by an internal combustion engine of the vehicle rotates relative to the stator 11, three-phase alternating current (AC) voltages are respectively induced in three coils of the stator 11. The regulator 12 may include six diodes configured to convert the AC voltages induced in the three coils of the stator 11 into DC voltages.

The automotive lithium-ion battery 100 is charged by DC power generated by the regulator 12. The load 20 operates by receiving DC power stored in the automotive lithium-ion battery 100 or DC power generated by the alternator 10. The load 20 may be, for example, a starter motor, an electronic control device such as an engine control unit (ECU), a headlight, a heater, an air conditioner, and/or a multimedia device.

A DC voltage output from the regulator 12 is about 13.5 V to about 14.5 V. An operating voltage range of a cell battery of an automotive battery varies according to a positive electrode active material. For example, a full charge voltage of a cell battery using lithium iron phosphate as a positive electrode active material, a so-called LFP cell battery, is about 3.6 V. Because a full charge voltage of an automotive battery in which four LFP cell batteries are connected in series is about 14.4 V, the automotive battery may be directly connected to the alternator 10. The automotive battery in which four LFP cell batteries are connected in series may replace a conventional automotive lead-acid battery.

However, a full charge voltage of a cell battery using another positive electrode active material, for example, nickel cobalt manganese oxide (NCM), lithium cobalt oxide (LCO), nickel cobalt aluminum oxide (NCA), or lithium manganese oxide (LMO), is about 4.2 V. Because a full charge voltage of an automotive battery in which four cell batteries are connected in series is about 16.8 V, the entire capacity may not be used, thereby causing inefficiency. Because a full charge voltage of an automotive battery in which three cell batteries are connected in series is about 12.6 V, overcharging may occur due to a voltage output from the alternator 10. To prevent these problems, the alternator 10 having a maximum output voltage of about 12.6 V may be used. However, the existing alternator 10 of the vehicle may not be changed.

According to the present disclosure, the automotive lithium-ion battery 100 includes a circuit for preventing overcharging due to an output voltage of the existing alternator 10.

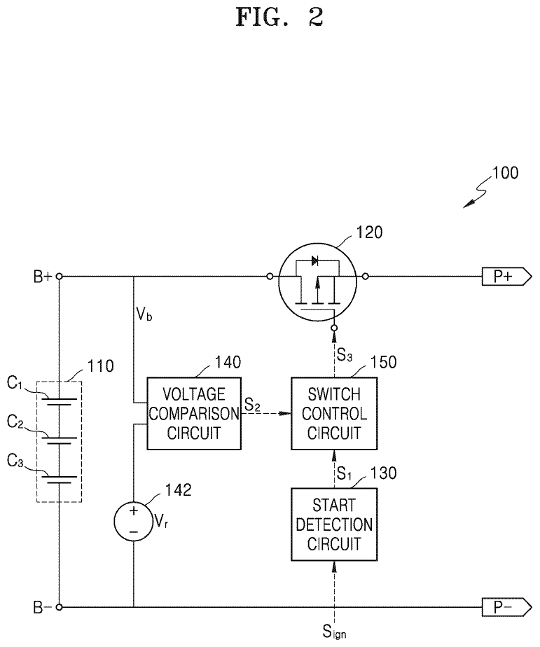

FIG. 2 is a block diagram illustrating an automotive lithium-ion battery, according to some embodiments of the present disclosure.

Referring to FIG. 2, the automotive lithium-ion battery 100 includes a battery 110, a metal-oxide-semiconductor field-effect transistor (MOSFET) switch 120, a start detection circuit 130, a voltage comparison circuit 140, and a switch control circuit 150.

The battery 110 includes a plurality of lithium-ion battery cells C₁, C₂, and C₃ connected in series between first and second battery terminals B+ and B−. The lithium-ion battery cells C₁, C₂, and C₃ where power is stored may be rechargeable secondary batteries.

The lithium-ion battery cells C₁, C₂, and C₃ may have a three-series connection configuration. The three lithium-ion battery cells C₁, C₂, and C₃ may be connected in series to each other to constitute the battery 110. According to the power storage capacity of the automotive lithium-ion battery 100, each of the lithium-ion battery cells C₁, C₂, and C₃ may have a plurality of battery cells connected in parallel. For example, the automotive lithium-ion battery 100 may include three sets of lithium-ion battery cells connected in series, and each set may include m lithium-ion battery cells connected in parallel. In this case, the automotive lithium-ion battery 100 may include 3×m lithium-ion battery cells.

A full charge voltage of the lithium-ion battery cells C₁, C₂, and C₃ may be 4 V or more. For example, a full charge voltage of the lithium-ion battery cells C₁, C₂, and C₃ may be 4.2 V or more. The lithium-ion battery cells C₁, C₂, and C₃ may be LCO battery cells in which a positive electrode active material includes lithium cobalt oxide. The lithium-ion battery cells C₁, C₂, and C₃ may be NCM battery cells in which a positive electrode active material includes lithium nickel cobalt manganese oxide. The lithium-ion battery cells C₁, C₂, and C₃ may be NCA battery cells in which a positive electrode active material includes lithium nickel cobalt nickel oxide. The lithium-ion battery cells C₁, C₂, and C₃ may be LMO battery cells in which a positive electrode active material includes lithium manganese oxide.

The MOSFET switch 120 is connected between the battery 110 and a pack terminal. As shown in FIG. 2, the MOSFET switch 120 may be a p-type MOSFET switch connected between the first battery terminal B+ and a first pack terminal P+. The p-type MOSFET switch 120 may have a body diode that allows current to flow only in a discharge direction of the battery 110. The p-type MOSFET switch 120 may have a body diode that blocks current flowing from the first pack terminal P+ to the first battery terminal B+.

The start detection circuit 130 receives a start signal S_{ign} and outputs a start detection signal S₁ for a set period of time in response to the start signal S_{ign}. The start detection circuit 130 may include a resistor-capacitor (RC) differential circuit.

The start signal S_{ign} is a signal for starting an internal combustion engine and may be a signal generated if a start key is turned or a signal generated if a start button is pressed. The set period of time may be preset based on a time taken for cold starting of the internal combustion engine. The set period of time may vary according to a temperature of cooling water.

The start detection circuit 130 may output the start detection signal S₁ while the start signal S_{ign} is input. The start detection signal S₁ may be output for the set period of time.

The start detection signal S₁ may be input to the switch control circuit 150, and the switch control circuit 150 may turn on the MOSFET switch 120 in response to the start detection signal S₁. Power stored in the battery 110 may be discharged through the body diode of the MOSFET switch even if the MOSFET switch 120 is turned off. However, because the body diode has considerable resistance, a magnitude of discharge current is limited, or the MOSFET switch 120 may be damaged if high-magnitude start current is discharged. According to some embodiments of the present disclosure, because the start detection circuit 130 forcibly turns on the MOSFET switch 120 at the time of starting, the automotive lithium-ion battery 100 may supply high-magnitude start current.

The voltage comparison circuit 140 outputs a voltage comparison signal S₂ by comparing a battery voltage V_{b} of the battery 110 with a reference voltage Vᵣ. The voltage comparison circuit 140 may include a comparator.

The reference voltage Vᵣ may be preset to be substantially the same as a full charge voltage of the battery 110 and may be supplied by a constant voltage source 142. For example, the voltage comparison circuit 140 may output the voltage comparison signal S₂ if the battery voltage V_{b} is lower than the reference voltage Vᵣ.

The voltage comparison signal S₂ may be input to the switch control circuit 150, and the switch control circuit 150 may turn on the MOSFET switch 120 in response to the voltage comparison signal S₂. The MOSFET switch 120 may be turned on if the battery voltage V_{b} is lower than the reference voltage Vᵣ by the comparison circuit 140, and the battery 110 may be charged by the alternator 10 (see FIG. 1) through the first and second pack terminals P+ and P−. If the battery voltage V_{b} is higher than the reference voltage Vᵣ, the MOSFET switch 120 may be turned off, and charging of the battery 110 may be stopped.

The switch control circuit 150 may receive the start detection signal S₁ and the voltage comparison signal S₂, and may output a switch control signal S₃ for controlling the MOSFET switch 120 based on the start detection signal S₁ and the voltage comparison signal S₂. The switch control circuit 150 may output the switch control signal Sa to a gate of the MOSFET switch 120 if any one of the start detection signal S₁ and the voltage comparison signal S₂ is received.

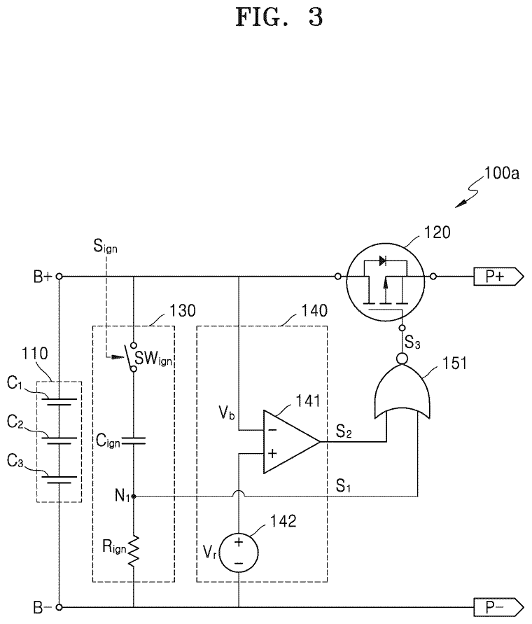

FIG. 3 is a block diagram illustrating an automotive lithium-ion battery, according to some embodiments of the present disclosure.

Referring to FIG. 3, an automotive lithium-ion battery 100a includes the battery 110, the MOSFET switch 120, the start detection circuit 130, a comparator 141, and a NOR gate 151.

The battery 110 includes a plurality of lithium-ion battery cells C₁, C₂, and C₃ connected in series between the first and second battery terminals B+ and B−. A full charge voltage of the lithium-ion battery cells C₁, C₂, and Camay be 4 V or more. The lithium-ion battery cells C₁, C₂, and C₃ may be LCO battery cells, NCM battery cells, NCA battery cells, or LMO battery cells.

The p-type MOSFET switch 120 may be connected between the first battery terminal B+ and the first pack terminal P+. The p-type MOSFET switch 120 may have a body diode that blocks current flowing from the first pack terminal P+ to the first battery terminal B+.

The start detection circuit 130 receives the start signal S_{ign} and outputs the start detection signal S₁ for a set period of time in response to the start signal S_{ign}.

The start detection circuit 130 may include a start switch SW_{ign} and a start capacitor C_{ign} connected in series between the first battery terminal B+ and an intermediate node N₁, and a start resistor R_{ign} connected between the intermediate node N₁ and the second battery terminal B−. The intermediate node N₁ may output the start detection signal S₁ having a high level only for the set period of time if the start switch SW_{ign} is turned on in response to the start signal S_{ign}.

If the start signal S_{ign} is not input, the start switch SW_{ign} is in an off-state, and the intermediate node N₁ outputs the start detection signal S₁ having the same voltage level as the second battery terminal B−, which is a low level.

If the start signal S_{ign} is input and the start switch SW_{ign} is turned on, the intermediate node N₁ outputs the start detection signal S₁ having the same voltage level as the first battery terminal B+, which is a high level. In this case, because charges stored in the start capacitor C_{ign} are all discharged, a voltage across the start capacitor C_{ign} are 0 V. If the start switch SW_{ign} is maintained in an on-state, current flowing through the start resistor R_{ign} accumulates in the start capacitor C_{ign}, and a voltage across the start capacitor C_{ign} gradually increases. A potential of the intermediate node N₁ gradually decreases, and a voltage level of the start detection signal S₁ also gradually decreases.

If a voltage level of the start detection signal S₁ is lower than a preset threshold value, the NOR gate 151 detects that the start detection signal S₁ having a low level is input. A time taken until a voltage level of the start detection signal S₁ changes from a high level to a low level corresponds to the set period of time. The set period of time is set to increase as a capacitance value of the start capacitor C_{ign} and a resistance value of the start resistor R_{ign} increase.

The set period of time may vary according to a temperature of cooling water, and to this end, the start resistor R_{ign} may have a resistance value inversely proportional to the temperature of the cooling water.

If inputting of the start signal S_{ign} is interrupted and the start switch SW_{ign} is turned off while the intermediate node N₁ outputs the start detection signal S₁ having a high level, the intermediate node N₁ outputs the start detection signal S₁ having a low level.

The comparator 141 outputs a voltage comparison signal S₂ by comparing the battery voltage V_{b} with the reference voltage Vᵣ. The comparator 141 may have a negative input terminal (−) to which the battery voltage V_{b} is input and a positive input terminal (+) connected to the constant voltage source 142 configured to output the reference voltage Vᵣ. The comparator 141 and the constant voltage source 142 may constitute the voltage comparison circuit 140.

The comparator 141 outputs the voltage comparison signal S₂ having a high level if the battery voltage V_{b} is lower than the reference voltage Vᵣ, and outputs the voltage comparison signal S₂ having a low level if the battery voltage V_{b} is higher than the reference voltage Vᵣ.

The NOR gate 151 may receive the start detection signal S₁ and the voltage comparison signal S₂, may perform a NOR logic operation on the start detection signal S₁ and the voltage comparison signal S₂, and may output the switch control signal S₃ to the p-type MOSFET switch 120.

If both the start detection signal S₁ and the voltage comparison signal S₂ have high levels, the NOR gate 151 outputs the switch control signal S₃ having a high level, and the p-type MOSFET switch 120 is turned off. If any one of the start detection signal S₁ and the voltage comparison signal S₂ has a high level, the NOR gate 151 outputs the switch control signal S₃ having a low level, and the p-type MOSFET switch 120 is turned on. If the battery voltage V_{b} is lower than the reference voltage Vᵣ, the p-type MOSFET switch is turned on, and if the start signal S_{ign} is input, the p-type MOSFET switch 120 is turned on for a set period of time.

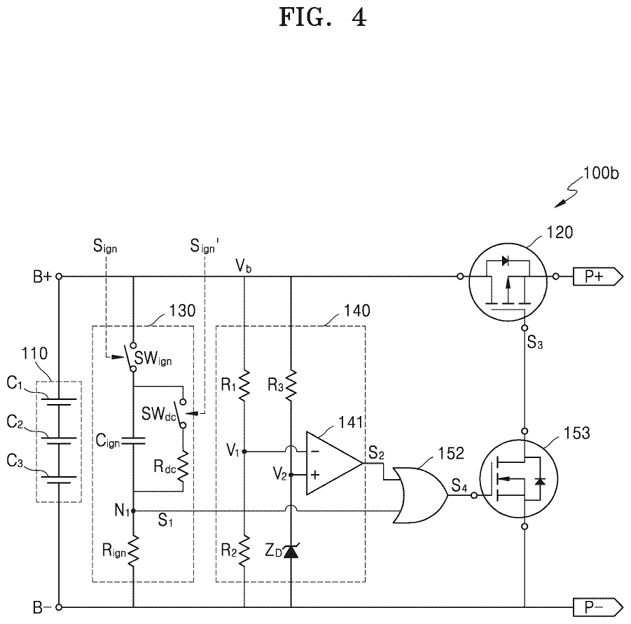

FIG. 4 is a block diagram illustrating an automotive lithium-ion battery, according to some embodiments of the present disclosure.

Referring to FIG. 4, an automotive lithium-ion battery 100b includes the battery 110, the p-type MOSFET switch 120, the start detection circuit 130, the comparator 141, an OR gate 152, and an n-type MOSFET switch 153. The battery 110 and the p-type MOSFET switch 120 have been described with reference to FIG. 3, and thus, a repeated description thereof will be omitted.

The start detection circuit 130 outputs the start detection signal S₁ for a set period of time in response to the start signal S_{ign}. The start detection circuit 130 may include the start switch SW_{ign} and the start capacitor C_{ign} connected in series between the first battery terminal B+ and the intermediate node N₁, and the start resistor R_{ign} connected between the intermediate node N₁ and the second battery terminal B−. The intermediate node N₁ may output the start detection signal S₁ having a high level only for the set period of time if the start switch SW_{ign} is turned on in response to the start signal S_{ign}.

The start detection circuit 130 may further include a discharge circuit connected in parallel to the start capacitor C_{ign}. The discharge circuit may discharge charges stored in the start capacitor C_{ign}. The discharge circuit may be configured to discharge charges stored in the start capacitor C_{ign} if the start switch SW_{ign} is turned off. For example, the discharge circuit may include a discharge switch SW_{dc} and a discharge resistor R_{dc} connected in series. The discharge switch SW_{dc} may be turned on in response to an inverted start signal S_{ign}′ that is an inverted signal of the start signal S_{ign}. According to some embodiments, the discharge switch SW_{dc} may be turned on only for a preset period of time if the start switch SW_{ign} is turned off.

If the start signal S_{ign} is not input, the start switch SW_{ign} is in an off-state, and the intermediate node N₁ outputs the start detection signal S₁ having a low level. If the start signal S_{ign} is input and the start switch SW_{ign} is turned on, the intermediate node N₁ outputs the start detection signal S₁ having a high level. If the start switch SW_{ign} is maintained in an on-state, a voltage across the start capacitor C_{ign} gradually increases and a voltage level of the start detection signal S₁ gradually decreases. If a voltage level of the start detection signal S₁ is lower than a preset threshold value, the OR gate detects that the start detection signal S₁ having a low level is input.

If inputting of the start signal S_{ign} is interrupted, the start switch SW_{ign} is turned off, and the intermediate node N₁ outputs the start detection signal S₁ having a low level. In this case, the discharge switch SW_{dc} is turned on, and a voltage across the start capacitor C_{ign} decreases to 0 V.

The comparator 141 outputs the voltage comparison signal S₂ by comparing a first voltage V₁ corresponding to the battery voltage V_{b} of the battery 110 with a second voltage V₂ corresponding to the reference voltage Vᵣ. The first voltage V₁ is a voltage obtained if the battery voltage V_{b} is divided by first and second resistors R₁ and R₂ connected in series between the first and second battery terminals B+ and B−. The second voltage V₂ is a Zener voltage of a Zener diode Z_{D}. A third resistor R₃ and the Zener diode Z_{D} are connected in series between the first and second battery terminals B+ and B−.

The comparator 141 may have a negative input terminal (−) to which the first voltage V₁ is input and a positive input terminal (+) connected to the constant voltage source 142 configured to output the reference voltage Vᵣ.

The comparator 141 outputs the voltage comparison signal S₂ having a high level if the first voltage V₁ is lower than the second voltage V₂, in other words, in a case where the battery voltage V_{b} is lower than the reference voltage Vᵣ. In contrast, the comparator 141 outputs the voltage comparison signal S₂ having a low level if the first voltage V₁ is higher than the second voltage V₂, in other words, in a case where the battery voltage V_{b} is higher than the reference voltage Vᵣ.

The OR gate 152 may receive the start detection signal S₁ and the voltage comparison signal S₂, may perform an OR logic operation on the start detection signal S₁ and the voltage comparison signal S₂, and may output a logic signal S₄ to the n-type MOSFET switch 153.

The OR gate 152 outputs the logic signal S₄ having a low level if both the start detection signal S₁ and the voltage comparison signal S₂ have low levels. If any one of the start detection signal S₁ and the voltage comparison signal S₂ has a high level, the OR gate 152 outputs the logic signal S₄ having a high level.

The n-type MOSFET switch 153 is connected between the second battery terminal B− or the second pack terminal P− and a gate of the p-type MOSFET switch 120. The n-type MOSFET switch 153 is controlled in response to the logic signal S₄. The n-type MOSFET switch 153 is turned on in response to the logic signal S₄ having a high level to output the switch control signal S₃ having a low level to the p-type MOSFET switch 120.

Therefore, if the battery voltage V_{b} is lower than the reference voltage Vᵣ, the p-type MOSFET switch 120 is turned on, and if the start signal S_{ign} is input, the p-type MOSFET switch 120 is turned on for a set period of time.

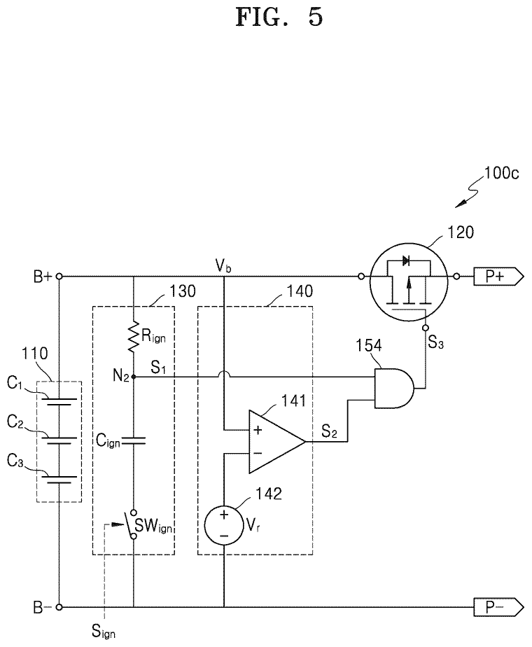

FIG. 5 is a block diagram illustrating an automotive lithium-ion battery, according to some embodiments of the present disclosure.

Referring to FIG. 5, an automotive lithium-ion battery 100c includes the battery 110, the p-type MOSFET switch 120, the start detection circuit 130, the voltage detection circuit 140, and an AND gate 154. The battery 110 and the p-type MOSFET switch 120 have been described with reference to FIG. 3, and thus, a repeated description thereof will be omitted.

The start detection circuit 130 outputs the start detection signal S₁ for a set period of time in response to the start signal S_{ign}. The start detection circuit 130 may include the start resistor R_{ign} connected between the first battery terminal B+ and an intermediate node N₂, and the start capacitor C_{ign} and the start switch SW_{ign} connected in series between the intermediate node N₂ and the second battery terminal B−. The intermediate node N₂ may output the start detection signal S₁ having a low level for the set period of time if the start switch SW_{ign} is turned on in response to the start signal S_{ign}. The start detection circuit 130 may further include a discharge circuit connected in parallel to the start capacitor C_{ign}.

If the start signal S_{ign} is not input, the start switch SW_{ign} is in an off-state, and the intermediate node N₂ outputs the start detection signal S₁ having a high level. If the start signal S_{ign} is input and the start switch SW_{ign} is turned on, the intermediate node N₂ outputs the start detection signal S₁ having a low level. If the start switch SW_{ign} is maintained in an on-state, a voltage across the start capacitor C_{ign} gradually increases, and a voltage level of the start detection signal S₁ gradually increases. If a voltage level of the start detection signal S₁ is higher than a preset threshold value, the AND gate 154 detects that the start detection signal S₁ having a high level is input. If inputting of the start signal S_{ign} is interrupted, the start switch SW_{ign} is turned off, and the intermediate node N₂ outputs the start detection signal S₁ having a high level. In this case, charges stored in the start capacitor C_{ign} may be discharged by the discharge circuit.

The comparator 141 outputs the voltage comparison signal S₃ by comparing the battery voltage V_{b} of the battery 110 with the reference voltage Vᵣ. The comparator 141 may have a positive input terminal (+) to which the battery voltage V_{b} is input and a negative input terminal (−) connected to the constant voltage source 142 configured to output the reference voltage Vᵣ. The comparator 141 and the constant voltage source 142 may constitute the voltage comparison circuit 140.

The comparator 141 outputs the voltage comparison signal S₂ having a low level if the battery voltage V_{b} is lower than the reference voltage Vᵣ, and outputs the voltage comparison signal S₃ having a high level if the battery voltage V_{b} is higher than the reference voltage Vᵣ.

The AND gate 154 may receive the start detection signal S₁ and the voltage comparison signal S₂, may perform an AND logic operation on the start detection signal S₁ and the voltage comparison signal S₂, and may output the switch control signal S₃ to the p-type MOSFET switch 120.

If both the start detection signal S₁ and the voltage comparison signal S₂ have high levels, the AND gate 154 outputs the switch control signal S₃ having a high level, and the p-type MOSFET switch 120 is turned off. If any one of the start detection signal S₁ and the voltage comparison signal S₂ has a low level, the AND gate 154 outputs the switch control signal S₃ having a low level, and the p-type MOSFET switch 120 is turned on. If the battery voltage V_{b} is lower than the reference voltage Vᵣ, the p-type MOSFET switch 120 is turned on, and if the start signal S_{ign} is input, the p-type MOFSET switch 120 is turned on for a set period of time.

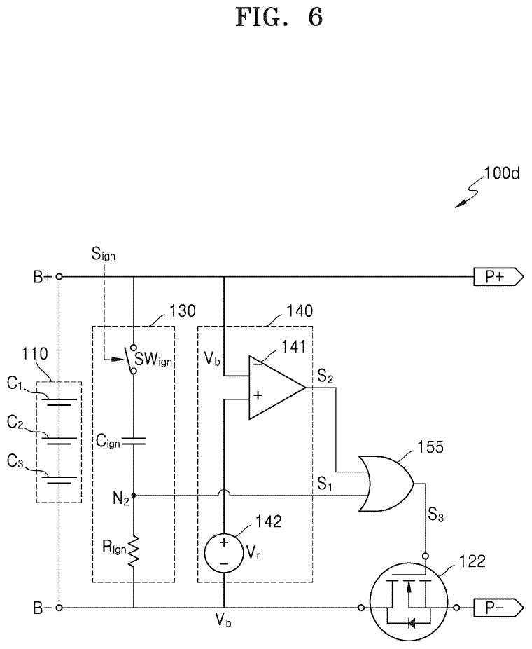

FIG. 6 is a block diagram illustrating an automotive lithium-ion battery, according to some embodiments of the present disclosure.

Referring to FIG. 6, an automotive lithium-ion battery 100d includes the battery 110, an n-type MOSFET switch 122, the start detection circuit 130, the voltage detection circuit 140, and an OR gate 155. The battery 110, the start detection circuit 130, and the voltage detection circuit 140 have been described with reference to FIG. 3, and thus, a repeated description thereof will be omitted.

The n-type MOSFET switch 122 may be connected between the second battery terminal B− and the second pack terminal P−. The n-type MOSFET switch 122 may have a body diode that blocks current flowing from the second battery terminal B− to the second pack terminal P−.

The start detection circuit 130 receives the start signal S_{ign}, and outputs the start detection signal S₁ for a set period of time in response to the start signal S_{ign}. The start detection circuit 130 may include the start switch SW_{ign} and the start capacitor C_{ign} connected in series between the first battery terminal B+ and the intermediate node N₁, and the start resistor R_{ign} connected between the intermediate mode N₁ and the second battery terminal B−. The intermediate node N₁ may output the start detection signal S₁ having a high level only for the set period of time if the start switch SW_{ign} is turned on in response to the start signal S_{ign}. The start detection circuit 130 may further include a discharge circuit connected in parallel to the start capacitor C_{ign}.

The comparator 141 outputs the voltage comparison signal S₂ by comparing the battery voltage V_{b} of the battery 110 with the reference voltage Vᵣ. The comparator 141 may have a negative input terminal (−) to which the battery voltage V_{b} is input and a positive input terminal (+) connected to the constant voltage source 142 configured to output the reference voltage Vᵣ. The comparator 141 and the constant voltage source 142 may constitute the voltage comparison circuit 140.

The OR gate 155 may receive the start detection signal S₁ and the voltage comparison signal S₂, may perform an OR logic operation on the start detection signal S₁ and the voltage comparison signal S₂, and may output the switch control signal S₃ to the n-type MOSFET switch 122.

If both the start detection signal S₁ and the voltage comparison signal S₂ have low levels, the OR gate outputs the switch control signal S₃ having a low level, and the n-type MOSFET switch 122 is turned off. If any one of the start detection signal S₁ and the voltage comparison signal S₂ has a high level, the OR gate outputs the switch control signal S₃ having a low level, and the n-type MOSFET switch 122 is turned on. If the battery voltage V_{b} is lower than the reference voltage Vᵣ, the p-type MOSFET switch 120 is turned on, and if the start signal S_{ign} is input, the p-type MOSFET switch 120 is turned on for a set period of time.

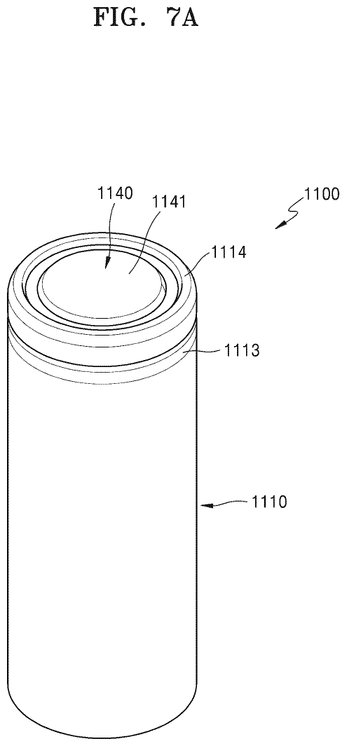

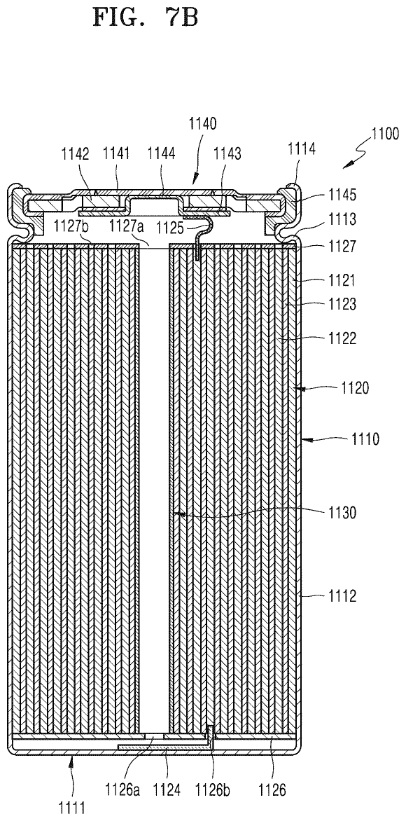

FIGS. 7A and 7B are a perspective view and a cross-sectional view illustrating a cylindrical lithium-ion battery cell mounted on an automotive lithium-ion battery, according to some embodiments of the present disclosure.

Referring to FIGS. 7A and 7B, a cylindrical lithium-ion battery cell 1100 includes a cylindrical can 1110, an electrode assembly 1120, and a cap assembly 1140. The cylindrical lithium-ion battery cell 1100 may further include a center pin 1130. The cap assembly 1140 performs a current interruption operation in the cylindrical lithium-ion battery cell 1100, and thus, may be referred to as a current interrupt device.

The cylindrical can 1110 may include a bottom portion 1111 having a substantially circular shape and a cylindrical side wall 1112 extending upward by a certain length from a circumference of the bottom portion 1111. An upper portion of the cylindrical can 110 may be open during a process of manufacturing the cylindrical lithium-ion battery cell 1100. Therefore, during the process of manufacturing the cylindrical lithium-ion battery cell 1100, the electrode assembly 1120 and the center pin 1130 may be inserted into the cylindrical can 1110 together with an electrolyte. The cylindrical can 1110 may be formed of, for example, but not limited to, steel, stainless steel, aluminum, an aluminum alloy, and/or an equivalent thereof.

In order to prevent the cap assembly 1140 from escaping to the outside, the cylindrical can 1110 may include a beading portion 1113 recessed inward at the bottom of a side surface of the cap assembly 1140 and a crimping portion 1114 bent inward at the top of the side surface of the cap assembly 1140.

The electrode assembly 1120 may be accommodated inside the cylindrical can 1110. The electrode assembly 1120 may include a negative electrode plate 1121 in which a negative electrode active material (e.g., graphite or carbon) is coated on a negative electrode current collector plate, a positive electrode plate 1122 in which a positive electrode active material (e.g., a transition metal oxide such as LiCoO₂, LiNiO₂, or LiMn₂O₄) is coated on a positive electrode current collector plate, and a separator 1123 located between the negative electrode plate 1121 and the positive electrode plate 1122 to prevent a short-circuit and allow only movement of lithium ions. Also, the negative electrode plate 1121, the positive electrode plate 1122, and the separator 1123 may be wound in a substantially cylindrical shape. For example, the negative electrode current collector plate may be formed of copper (Cu) foil, the positive electrode current collector plate may be formed of aluminum (AI) foil, and the separator may be formed of polyethylene (PE) or polypropylene (PP), but the present disclosure is not limited thereto.

A negative electrode tab 1124 protruding and extending downward by a certain length may be welded to the negative electrode plate 1121, and an positive electrode tab 1125 protruding and extending upward by a certain length may be welded to the positive electrode plate 1122, or vice versa. In other embodiments, the negative electrode tab 1124 may be formed of copper (Cu) or nickel (NI), and the positive electrode tab 1125 may be formed of aluminum (AI), but the present disclosure is not limited thereto.

The negative electrode tab 1124 of the electrode assembly 1120 may be welded to the bottom portion 1111 of the cylindrical can 1110. Therefore, the cylindrical can 1110 may operate as a negative electrode. In contrast, the positive electrode tab 1125 may be welded to the bottom portion 1111 of the cylindrical can 1110, and in this case, the cylindrical can 1110 may operate as a positive electrode.

In some embodiments, a first insulation plate 1126 coupled to the cylindrical can 1110 and including a first hole 1126a at the center and a second hole 1126b outside the first hole 1126a may be located between the electrode assembly 1120 and the bottom portion 1111. The first insulation plate 1126 prevents the electrode assembly 1120 from electrically contacting the bottom portion 1111 of the cylindrical can 1110. The first insulation plate 1126 prevents the positive electrode plate 1122 of the electrode assembly 1120 from electrically contacting the bottom portion 1111. If a large amount of gas is generated due to abnormality of the cylindrical lithium-ion battery cell 1100, the first hole 1126a allows the gas to rapidly move upward through the center pin 1130 and the second hole 1126b allows the negative electrode tab 1124 to penetrate therethrough and be welded to the bottom portion 1111.

Also, a second insulation plate 1127 coupled to the cylindrical can 1110 and including a first hole 1127a at the center and a plurality of second holes 1127b outside the first hole 1127a may be located between the electrode assembly 1120 and the cap assembly 1140. The second insulation plate 1127 prevents the electrode assembly 1120 from electrically contacting the cap assembly 1140. The second insulation plate 1127 prevents the negative electrode plate 1121 of the electrode assembly 1120 from electrically contacting the cap assembly 1140. If a large amount of gas is generated due to abnormality of the cylindrical lithium-ion battery cell 1100, the first hole 1127a allows the gas to rapidly move toward the cap assembly 1140 and the second holes 1127b allow the positive electrode tab 1125 to penetrate therethrough and be welded to the cap assembly 1140. Also, the remaining second holes 1127b allow an electrolyte to rapidly flow into the electrode assembly 1120 in an electrolyte injection process.

Also, because the first holes 1126a and 1127a of the first and second insulation plates 1126 and 1127 have diameters less than a diameter of the center pin 1130, the center pin 1130 is prevented from electrically contacting the bottom portion 1111 of the cylindrical cap 1110 or the cap assembly 1140 due to external impact.

The center pin 1130 has a hollow circular pipe shape and may be coupled to the center of the electrode assembly 1120. The center pin 1130 may be formed of, for example, but not limited to, steel, stainless steel, aluminum, an aluminum alloy, and/or polybutylene terephthalate. The center pin 1130 suppresses deformation of the electrode assembly 1120 during charging and discharging of the battery and functions as a passage through which gas generated inside the cylindrical lithium-ion battery cell 1100 moves. If necessary, the center pin 1130 may be omitted.

The cap assembly 1140 may include a top plate 1141, a middle plate 1142, an insulation plate 143, and a bottom plate 1144. The middle plate 1142 is located under the top plate 1141 and may have a substantially flat shape. The insulation plate 1143 may be formed in a circular ring shape having a certain width if viewed from the bottom. Also, the insulation plate 1143 insulates the middle plate 1142 and the bottom plate 1144 from each other. The insulation plate 1143 may be located between, for example, the middle plate 1142 and the bottom plate 1144 to then be ultrasonically welded, but the present disclosure is not limited thereto.

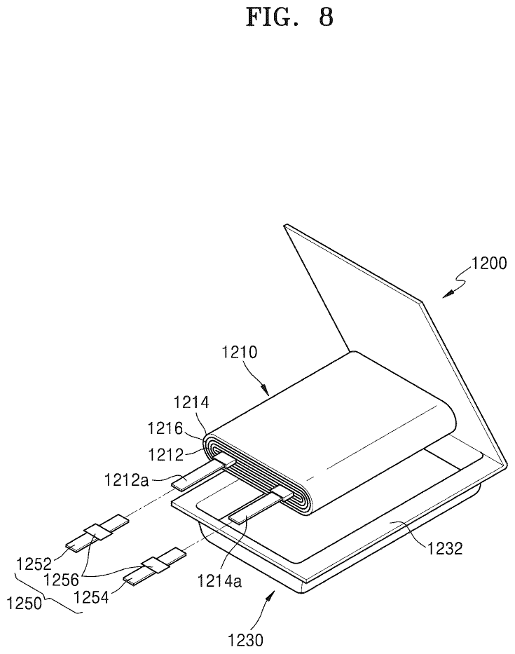

FIG. 8 is a partial perspective view illustrating a structure of a pouch-type lithium-ion battery cell mounted on an automotive lithium-ion battery, according to embodiments of the present disclosure.

Referring to FIG. 8, a pouch-type lithium-ion battery cell 1200 includes an electrode assembly 1210, and a pouch 1230 in which the electrode assembly 1210 is accommodated.

The electrode assembly 1210 includes a negative electrode plate 1212 that is a first electrode plate, a positive electrode plate 1214 that is a second electrode plate, and a separator 1216 located between the negative electrode plate 1212 and the positive electrode plate 1214. The negative electrode plate 1212 includes a negative electrode tab 1212a electrically connected to a negative electrode uncoated portion, and the positive electrode plate 1214 includes a positive electrode tab 1214a electrically connected to a positive electrode uncoated portion. The negative electrode tab 1212a and the positive electrode tab 1214a are respectively welded to a negative electrode lead 1252 and a positive electrode lead 1254 of an external terminal to be electrically connected to the outside. A tab film 1256 for insulation from the pouch 1230 is attached to the negative electrode lead 1252 and the positive electrode lead 1254.

In a state where the electrode assembly 1210 is accommodated in the pouch 1230, sealing portions 1232 of edges of the pouch 1230 contact each other to be sealed. In this case, the sealing portions 1232 are sealed in a state where the tab film 1256 is located between the sealing portions 1232. As shown in FIG. 8, a form in which the tab film 1256 is attached to each of the negative electrode tab 1212a and the positive electrode tab 1214a is defined as a ‘separable tab film’. This sealing structure may be defined as a separable sealing structure.

The sealing portions 1232 of the pouch 1230 are formed of a heat-fusible material and are sealed by adhering heat-fusible layers to each other. Because a heat-fusible material generally has weak adhesion to a metal, the tab film 1256 that is a thin film is attached to a tab to be fused to the pouch 1230. However, in the separable sealing structure, the tab film 1256 should be attached to each tab, welded to the tab, and then heat-fused with the pouch 1230, thereby reducing workability and productivity.

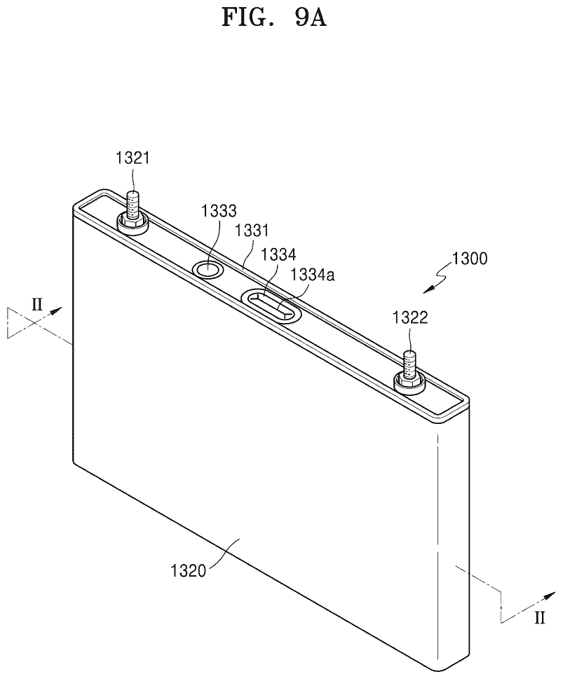

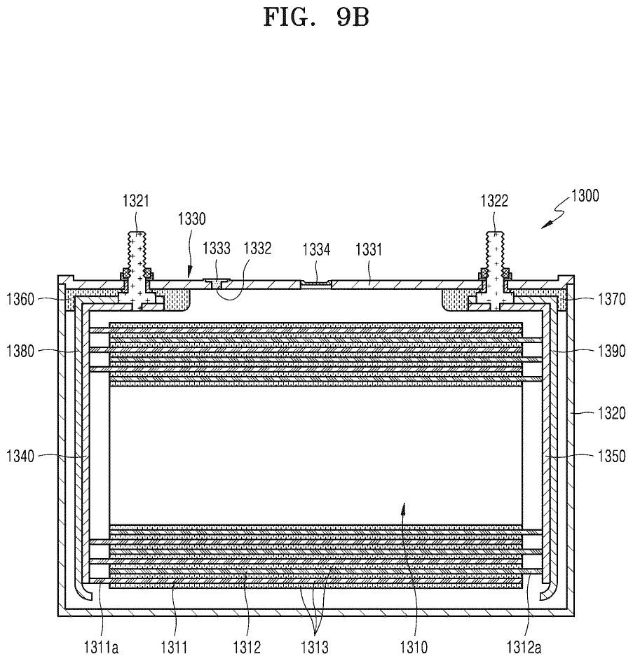

FIG. 9A is a perspective view illustrating a prismatic lithium-ion battery cell mounted on an automotive lithium-ion battery, according to some embodiments of the present disclosure. FIG. 9B is a cross-sectional view taken along line II-II of FIG. 9A.

Referring to FIGS. 9A and 9B, a prismatic lithium-ion battery cell 1300 includes at least one electrode assembly 1310 wound with a separator 1313 as an insulator between a positive electrode 1311 and a negative electrode 1312, a case 1320 in which the electrode assembly 1310 is accommodated, and a cap assembly 1330 coupled to an opening of the case 1320.

The prismatic lithium-ion battery cell 1300 is, for example, a lithium-ion battery cell having a prismatic shape. However, the present disclosure is not limited thereto and may be applied to any of various types of batteries such as a lithium polymer battery or a cylindrical battery.

Each of the positive electrode 1311 and the negative electrode 1312 may include a current collector formed of a thin film metal foil having a coated portion on which an active material is coated and uncoated portions 1311a and 1312a on which an active material is not coated.

The positive electrode 1311 and the negative electrode 1312 are wound after interposing the separator 1313, which is an insulator, therebetween. However, the present disclosure is not limited thereto, and the electrode assembly 1310 may have a structure in which a positive electrode and a negative electrode each formed of a plurality of sheets are alternately stacked with a separator therebetween.

The case 1320 may form an overall outer appearance of the prismatic lithium-ion battery cell 1300 and may be formed of a conductive metal such as aluminum, an aluminum alloy, or nickel-plated steel. Also, the case 1320 may provide a space in which the electrode assembly 1310 is accommodated.

The cap assembly 1330 may include a cap plate 1331 covering the opening of the case 1320, and each of the case 1320 and the cap plate 1331 may be formed of a conductive material. Positive and negative electrode terminals 1321 and 1322 electrically connected to the positive electrode 1311 or the negative electrode 1312 may penetrate the cap plate 1331 and may protrude outward.

Also, outer peripheral surfaces of upper pillars of the positive and negative electrode terminals 1321 and 1322 protruding outward from the cap plate 1331 may be threaded and may be fixed to the cap plate 1331 with nuts. However, the present disclosure is not limited thereto, and the positive and negative electrode terminals 1321 and 1322 may have a rivet structure and may be riveted or welded to the cap plate 1331.

Also, the cap plate 1331 may be formed of a thin plate and may be coupled to the opening of the case 1320, and an electrolyte injection port 1332 into which a sealing stopper 1333 may be provided may be formed in the cap plate 1331 and a vent portion 1334 having a notch 1334a may be provided.

The positive and negative electrode terminals 1321 and 1322 may be electrically connected to current collectors including first and second current collectors 1340 and 1350 (hereinafter, referred to as positive and negative electrode current collectors) welded to the positive electrode uncoated portion 1311a and the negative electrode uncoated portion 1312a.

For example, the positive and negative electrode terminals 1321 and 1322 may be welded to the positive and negative electrode current collectors 1340 and 1350. However, the present disclosure is not limited thereto, and the positive and negative electrode terminals 1321 and 1322 and the positive and negative electrode current collectors 1340 and 1350 may be integrally formed.

Also, an insulation member may be provided between the electrode assembly 1310 and the cap plate 1331. The insulation member may include first and second lower insulation members 1360 and 1370, and each of the first and second lower insulation members 1360 and 1370 may be provided between the electrode assembly 1310 and the cap plate 1331.

Also, according to the present embodiment, one end of a separation member may face one side surface of the electrode assembly 1310 and may be provided between the insulation member and the positive or negative electrode terminal 1321 or 1322. The separation member may include first and second separation members 1380 and 1390. Therefore, ends of the first and second separation members 1380 and 1390 provided to face one side surface of the electrode assembly 1310 may be provided between the first and second lower insulation members 1360 and 1370 and the positive and negative electrode terminals 1321 and 1322.

As a result, the positive and negative electrode terminals 1321 and 1322 welded to the positive and negative electrode current collectors 1340 and 1350 may be coupled to ends of the first and second lower insulation members 1360 and 1370 and the first and second separation members 1380 and 1390.

The particular implementations shown and described herein are illustrative examples of the present disclosure and are not intended to otherwise limit the scope of the present disclosure in any way. For the sake of brevity, conventional electronic elements, control systems, software and other functional aspects of the systems may not be described in detail. Also, lines or members connecting elements illustrated in the drawings are merely illustrative of functional connections and/or physical or circuit connections. In an actual device, the connections between elements may be represented by many alternative or additional functional connections, physical connections, or circuit connections.

In the embodiments (particularly, in claims), the term “the” and designation terms similar thereto may correspond to both a singular form and a plural form. Furthermore, recitation of ranges of values herein are merely intended to serve as a shorthand method of referring individually to each separate value falling within the range, unless otherwise indicated herein, and each separate value is incorporated into the specification as if it were individually recited herein. Also, operations of all methods described herein may be performed in any suitable order unless otherwise indicated herein or otherwise clearly contradicted by context. The present disclosure is not limited to the order of the operations.

The use of any and all examples, or exemplary language (e.g., “such as”) provided herein, is intended merely to better describe the present disclosure and does not pose a limitation on the scope of the embodiments unless otherwise claimed. Also, it will be understood by one of ordinary skill in the art that numerous modifications, adaptations, and changes will be made according to design conditions and factors without departing from the spirit and scope of the appended claims.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with particular embodiments may be used alone or in combination with features, characteristics, and/or elements described in connection with other embodiments unless otherwise specifically indicated. Accordingly, the spirit of the present disclosure is not limited to the above-described embodiments, and all ranges equivalent to the claims or equivalently changed therefrom as well as the claims described below belong to the scope of the spirit of the present disclosure.

According to the present disclosure, an automotive lithium-ion battery may be used instead of a lead-acid battery even without changing an electrical system of a vehicle.

However, effects obtainable from the present disclosure may not be limited by the above-mentioned effects. Other unmentioned effects may be clearly understood from the following description by one of ordinary skill in the art to which the present disclosure pertains.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the present disclosure as defined by the following claims.

What is claimed is:

1. An automotive lithium-ion battery comprising:
a battery comprising a plurality of lithium-ion battery cells connected in series between a first battery terminal and a second battery terminal;
a metal-oxide-semiconductor field-effect transistor (MOSFET) switch connected between the battery and a pack terminal;
a start detection circuit configured to receive a start signal and output a start detection signal for a set period of time in response to the start signal;
a voltage comparison circuit configured to output a voltage comparison signal by comparing a battery voltage of the battery with a reference voltage; and
a switch control circuit configured to output a switch control signal for controlling the MOSFET switch based on the start detection signal and the voltage comparison signal.

2. The automotive lithium-ion battery as claimed in claim 1, wherein the plurality of lithium-ion battery cells have a three-series connection configuration.

3. The automotive lithium-ion battery as claimed in claim 1, wherein the plurality of lithium-ion battery cells are lithium cobalt oxide (LCO), nickel cobalt manganese oxide (NCM), nickel cobalt aluminum oxide (NCA), or lithium manganese oxide (LMO) battery cells having a full charge voltage of 4 V or more.

4. The automotive lithium-ion battery as claimed in claim 1, wherein the MOSFET switch is a p-type MOSFET switch connected between the first battery terminal and a first pack terminal.

5. The automotive lithium-ion battery as claimed in claim 4, wherein the start detection circuit comprises a start switch and a start capacitor connected in series between the first battery terminal and an intermediate node, and a start resistor connected between the intermediate node and the second battery terminal,
wherein the intermediate node is configured to output the start detection signal having a high level only for the set period of time when the start switch is turned on in response to the start signal.

6. The automotive lithium-ion battery as claimed in claim 5, wherein the start detection circuit further comprises a discharge circuit connected in parallel to the start capacitor,
wherein the discharge circuit is configured to discharge charges stored in the start capacitor when the start switch is turned off.

7. The automotive lithium-ion battery as claimed in claim 4, wherein the voltage comparison circuit comprises a comparator comprising a negative input terminal to which a first voltage corresponding to the battery voltage is input and a positive input terminal to which a second voltage corresponding to the reference voltage is input,
wherein the comparator is configured to output the voltage comparison signal having a high level when the battery voltage is lower than the reference voltage.

8. The automotive lithium-ion battery as claimed in claim 4, wherein the switch control circuit is a NOR gate configured to perform a NOR logic operation on the start detection signal and the voltage comparison signal and output the switch control signal to the MOSFET switch.

9. The automotive lithium-ion battery as claimed in claim 4, wherein the switch control circuit comprises:
an OR gate configured to perform an OR logic operation on the start detection signal and the voltage comparison signal and output a logic signal; and
an n-type MOSFET switch connected between the second battery terminal or a second pack terminal and a gate of the MOSFET switch to output the switch control signal having a low level in response to the logic signal having a high level.

10. The automotive lithium-ion battery as claimed in claim 4, wherein the start detection circuit comprises a start resistor connected between the first battery terminal and an intermediate node, and a start capacitor and a start switch connected in series between the intermediate node and the second battery terminal,
wherein the intermediate node is configured to output the start detection signal having a low level only for the set period of time when the start switch is turned on in response to the start signal.

11. The automotive lithium-ion battery as claimed in claim 10, wherein the voltage comparison circuit comprises a comparator comprising a positive input terminal to which a first voltage corresponding to the battery voltage is input and a negative input terminal to which a second voltage corresponding to the reference voltage is input,
wherein the comparator is configured to output the voltage comparison signal having a low level when the battery voltage is lower than the reference voltage.

12. The automotive lithium-ion battery as claimed in claim 11, wherein the switch control circuit is an AND gate configured to perform an AND logic operation on the start detection signal and the voltage comparison signal and output the switch control signal to the MOSFET switch.

13. The automotive lithium-ion battery as claimed in claim 1, wherein the MOSFET switch is an n-type MOSFET switch connected between the second battery terminal and a second pack terminal.

14. The automotive lithium-ion battery as claimed in claim 13, wherein the start detection circuit comprises a start switch and a start capacitor connected in series between the first battery terminal and an intermediate node, and a start resistor connected between the intermediate node and the second battery terminal,
wherein the intermediate node is configured to output the start detection signal having a high level only for the set period of time when the start switch is turned on in response to the start signal.

15. The automotive lithium-ion battery as claimed in claim 14, wherein the voltage comparison circuit comprises a comparator comprising a positive input terminal to which a first voltage corresponding to the battery voltage is input and a negative input terminal to which a second voltage corresponding to the reference voltage is input,
wherein the comparator is configured to output the voltage comparison signal having a high level when the battery voltage is lower than the reference voltage.

16. The automotive lithium-ion battery as claimed in claim 15, wherein the switch control circuit is an OR gate configured to perform an OR logic operation on the start detection signal and the voltage comparison signal and output the switch control signal to the MOSFET switch.

17. A protection circuit comprising:
a metal-oxide-semiconductor field-effect transistor (MOSFET) switch connected between a pack terminal and a first battery terminal to which a plurality of lithium-ion battery cells are connected in series;
a start detection circuit configured to receive a start signal and output a start detection signal for a set period of time in response to the start signal;
a voltage comparison circuit configured to output a voltage comparison signal by comparing a battery voltage between the first battery terminal and a second battery terminal with a reference voltage; and
a switch control circuit configured to output a switch control signal for controlling the MOSFET switch based on the start detection signal and the voltage comparison signal.

18. The protection circuit as claimed in claim 17, wherein the start detection circuit comprises a resistor-capacitor (RC) differential circuit comprising a start switch and a start capacitor connected in series between the first battery terminal and an intermediate node configured to output the start detection signal, and a start resistor connected between the intermediate node and the second battery terminal.

19. The protection circuit as claimed in claim 17, wherein the voltage comparison circuit comprises a comparator configured to receive a first voltage corresponding to the battery voltage and a second voltage corresponding to the reference voltage and output the voltage comparison signal by comparing the first voltage with the second voltage.

20. The protection circuit as claimed in claim 17, wherein the switch control circuit comprises a logic gate circuit configured to perform a logic operation on the start detection signal and the voltage comparison signal and output the switch control signal.
